(19) United States
(12) Patent Application Publication
(10) Pub. No.: US 2014/0266250 A1
(43) Pub. Date: Sep. 18, 2014

(54) SENSOR EXTENSIONS FOR CAPACITIVE SENSORS

(71) Applicant: Pure Imagination, LLC, Vancouver, WA (US)

(72) Inventors: Michael Wallace, Vancouver, WA (US); Philip T. Odom, Portland, OR (US)

(21) Appl. No.: 14/217,020

(22) Filed: Mar. 17, 2014

Related U.S. Application Data
(60) Provisional application No. 61/799,162, filed on Mar. 15, 2013.

(51) Int. Cl. G01R 27/26

(52) U.S. Cl. CPC G01R 27/2605
USPC 324/658

(57) ABSTRACT

Sensor extensions are a way of connecting capacitive sensors to a system using capacitive coupling rather than a conductive connection. Sensor extensions enable many unique applications. For example, a sensing system can be designed to support interchangeable sensor modules without exposed metal contacts. In another application, multi-layer sensor assemblies can be implemented without requiring connections between layers (“vias”), simplifying routing and allowing the area of touch sensors to be expanded. In yet another application, product packaging can include sensors that are extensions of the product's sensors. In-store display solutions can use the technique to make products on display touch-sensitive.

### CROSS-REFERENCE TO RELATED APPLICATION

The present application claims priority to co-pending U.S. Provisional Application No. 61/799,162 filed on 15 Mar. 2013, incorporated herein by reference.

### FIELD OF THE INVENTION

The present invention relates to capacitive sensors. More particularly, the present invention relates to capacitive touch and object sensors.

### BACKGROUND

Capacitive sensors are usually connected directly to a system's measurement electronics module by a wire, conductive trace, or other ways, depending on the construction of the system. There are many applications where this is not convenient. Systems that use interchangeable sensor modules are one example. Detecting touch on an object that simply can't be electrically connected to the system is another example. In other cases, the connections for capacitive sensors are difficult to route in a single layer, but multi-layer sensor assemblies that include connections between layers are much more expensive to produce than assemblies that use multiple, unconnected layers.

What is needed is a way to connect capacitive sensors to electronics without a direct electrical connection.

### SUMMARY

Sensor extensions are a way of connecting capacitive sensors to a system using capacitive coupling rather than a conductive connection. Sensor extensions enable many unique applications. For example, a sensing system can be designed to support interchangeable sensor modules without exposed metal contacts. In another application, multi-layer sensor assemblies can be implemented without requiring connections between layers (“vias”), simplifying routing and allowing the area of touch sensors to be expanded. In yet another application, product packaging can include sensors that are extensions of the product's sensors. In-store display solutions can use the technique to make products on display touch-sensitive.

### BRIEF DESCRIPTION OF THE DRAWINGS

The present invention will be described by way of exemplary embodiments, but not limitations, illustrated in the accompanying drawings in which like references denote similar elements, and in which:

The accompanying drawings, which are incorporated into and constitute a part of this specification, illustrate one or more embodiments of the invention and, together with the detailed description, serve to explain the principles and implementations of the invention.

FIG. 1 shows a sensor extension system.

FIG. 2 shows a first embodiment interactive trading card game.

FIG. 3 shows a second embodiment interactive trading card game.

FIG. 4 shows a third embodiment interactive trading card game.

FIG. 5 shows a fourth embodiment interactive trading card game.

FIG. 6 shows the sensor extension system of FIG. 1 with the various capacitances experienced by the system modeled as discrete capacitors.

FIG. 7A shows a lower layer of a multi-layer sensor.

FIG. 7B shows an upper layer of the multi-layer sensor.

FIG. 7C shows the multi-layer sensor comprising the lower layer of FIG. 7A overlaid with the upper layer of FIG. 7B.

FIG. 8A shows a row sensor layer of a sensor matrix.

FIG. 8B shows a column sensor layer of the sensor matrix.

FIG. 8C shows the sensor matrix comprising the row sensor layer of FIG. 8A overlaid with the column sensor layer of FIG. 8B.

FIG. 9 shows a sensor assembly with sensor extensions coupled to a printed circuit board.

FIG. 10 shows sensor extensions that couple to sensors in a product incorporated into the product's packaging.

FIGS. 11A and 11B show sensor extensions used to produce an in-store product display that uses the product itself as a sensor extension.

### DETAILED DESCRIPTION

Before beginning a detailed description of the subject invention, mention of the following is in order. When appropriate, like reference materials and characters are used to designate identical, corresponding, or similar components in different figures. The figures associated with this disclosure typically are not drawn with dimensional accuracy to scale, i.e., such drawings have been drafted with a focus on clarity of viewing and understanding rather than dimensional accuracy.

In the interest of clarity, not all of the routine features of the implementations described herein are shown and described. It will, of course, be appreciated that in the development of any such actual implementation, numerous implementation-specific decisions must be made in order to achieve the developer's specific goals, such as compliance with application and business related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

Use of directional terms such as “upper,” “lower,” “above,” “below”, “in front of,” “behind,” etc. are intended to describe the positions and/or orientations of various components of the invention relative to one another as shown in the various Figures and are not intended to impose limitations on any position and/or orientation of any embodiment of the invention relative to any reference point external to the reference.

Those skilled in the art will recognize that numerous modifications and changes may be made to the exemplary embodiment(s) without departing from the scope of the claimed invention. It will, of course, be understood that modifications of the invention, in its various aspects, will be apparent to those skilled in the art, some being apparent only after study, others being matters of routine mechanical, chemical and electronic design. No single feature, function or property of the exemplary embodiment(s) is essential. Other embodiments are possible, their specific designs depending upon the particular application. As such, the scope of the invention should not be limited by the particular embodiments herein described but should be defined only by the appended claims and equivalents thereof.

### Exemplary Embodiment of a Sensor Extension

A sensor extension is a capacitive sensor that is connected to the system's measurement electronics module through one or more capacitive links. FIG. 1 shows a sensor extension system 100 with an extended sensor 101 and a measurement electronics module 106. The extended sensor 101 comprises a primary sensor 102 and a sensor extension 104. The primary sensor 102 comprises a primary extension pad 108 and a primary conductive trace 110, with the primary extension pad 108 connected to the measurement electronics module 106 with the primary conductive trace 110.

The sensor extension 104 comprises a secondary extension pad 112, a sensor pad 114 and a secondary conductive trace 116 there between. A capacitive link is formed by the primary extension pad 108 of the primary sensor 102 in close proximity to the secondary extension pad 112 of the sensor extension 104.

An insulating layer 118 or layers separates the extension pads 108, 112 so that there is no conductive contact between sensor extension 104 and the measurement electronics module 106. In some embodiments, the insulating layer 118 is a dielectric film. In other embodiments, the insulating layer 118 is an air gap.

In some embodiments, the extension pads 108, 112 partially or completely overlap each other, but on different planes and separated by the insulating layer 118. In other embodiments the extension pads 108, 112 are coplanar as is the separating insulating layer 118.

The measurement electronics module 106 is configured for measuring capacitance on the primary conductive trace 110 or stated differently, for measuring capacitance between the primary conductive trace 110 and a system ground. This is done by one of several well-known methods, most of which involve charging the primary conductive trace 110 to voltage, then connecting to system ground and timing the rate of discharge.

Components conductively connected to the primary conductive trace 110, such as the primary extension pad 108, will change the capacitance on the primary conductive trace 110 as measured by the measurement electronics module 106. Stated differently, the measurement electronics module 106 is configured for measuring capacitance of the primary sensor 102. Components capacitively coupled to the primary sensor 102, such as the sensor extension 104, will change the capacitance on the primary conductive trace 110 measured by the measurement electronics module 106.

In some embodiments, the sensor extension 104 does not have a separate sensor pad 114 and secondary conductive trace 116, just the secondary extension pad 112. The secondary extension pad 112 functions both as the secondary extension pad 112 and as the sensor pad 114. Stated differently, in such embodiments, the secondary extension pad 112 is also the sensor pad 114.

### Theory of Operation, Optimization

The typical configuration for a capacitive sensor is a conductive pad or pads connected to a measurement system by a conductive trace or wire. The sensor pad(s) is usually covered by an electrical insulator and does not make direct contact with the objects or people it is designed to detect.

In sensor extension applications, the direct trace or wire connection is broken into 2 or more segments with capacitively coupled connections between the segments. In effect, the sensor is connected to the measurement system through one or more capacitors.

The capacitive links reduce the sensitivity of the sensors, but this can usually be overcome. How much the sensitivity will be affected can be determined by calculation. For a basic self-capacitance sensor, the system measures a sensor's capacitance to ground and detects an event as a change in this value. The sensor has a base level capacitance C_{B} due to coupling between the sensor and system ground. A touch to the sensor or the presence of an object on the sensor increases this capacitance by the amount of a touch capacitance C_{T}. The total capacitance of the sensor is then C_{B}+C_{T}, and the increase is the full value of C_{T}.

FIG. 6 shows the sensor extension system 100 of FIG. 1 with the various capacitances it experiences modeled as discrete capacitors. The sensor base capacitance C_{B} of the primary sensor 102 has counterpart in an extension base capacitance C_{BX} in the sensor extension 104. The primary base capacitance C_{B} is the capacitance of the primary sensor 102 relative to ground. The extension base capacitance C_{BX} is the capacitance between the sensor extension 104 relative to ground. In the sensor extension system 100, the increase in capacitance from addition of the touch capacitance C_{T} is reduced due to the presence of the sensor extension capacitance C_{X}. The base capacitance of the extended sensor 101 (i.e., the sensor extension system 100—the primary sensor 102 combined with the sensor extension 104) is

$${C}_{BE} = {C}_{B} + \frac{{C}_{X} {C}_{BX}}{{C}_{X} + {C}_{BX}} .$$

The total capacitance of the extended sensor 101 (extended sensor total capacitance C_{Tot}) when the sensor extension is touched or when a conductive object is adjacent is

$${C}_{Tot} = {C}_{B} + \frac{{C}_{X} ( {C}_{BX} + {C}_{T} )}{{C}_{X} + {C}_{BX} + {C}_{T}} .$$

Analyzing these formulas leads to two important facts. First, the larger the value of sensor extension capacitance C_{X}, the less impact it has on the sensitivity of the sensor (change in total sensor capacitance C_{Tot} when touch capacitance C_{T} is changed). Second, the change in capacitance due to the addition of touch capacitance C_{T} is dependent on sensor extension base capacitance C_{BX} in the sensor extension case. The smaller sensor extension base capacitance C_{BX} is, the smaller the sensitivity of the total sensor capacitance C_{Tot}. Maximizing sensor extension capacitance C_{X} and minimizing sensor extension base capacitance C_{BX} achieves the largest sensor sensitivity.

The sensor extension capacitance C_{X} can be increased by making the extension pads 108, 112 larger, by reducing their separation, and by insulating the pads with a higher dielectric constant material. Sensor extension base capacitance C_{BX} can be reduced by placing the sensor extension 104 away from any grounded metal such as a shield, by mounting the sensor extension 104 on a low-dielectric material such as foam, and by separating the sensor extension 104 from other sensor extensions as much as possible.

### Touch with Extended Sensors

Extended sensors work well as touch sensors. The reduced sensitivity of extended sensors has less impact on touch detection than on object or proximity detection applications.

In systems where the extended portion of the extended sensor is on a removable module (see applications below for examples), the extension pad on the base unit can itself be used as a touch sensor as well when no module is present.

Because the sensor extension is isolated from the system electronics, it is also not necessary that the extension's touch pad be electrically insulated. Directly touching the exposed conductive material of the extension will result in higher sensitivity, possibly at the expense of the durability of the extension.

### Object Detection with Extended Sensors

It is feasible to use a set of extended sensors to perform object detection just as normal sensors can be used, including the use of multi-sensor object identity systems. This capability can be used, for example, to allow a multi-level play set to include sensors in the upper levels of the set without requiring a conductive connection back to the system's electronics.

A set of extended sensors is used—one for the measurement signal and one for a ground. In contrast, a touch sensor only uses a single extended sensor for measurement, omitting the extended sensor for the ground. Since the human body has a significantly large capacitance, a touch sensor can rely on a general system ground for a return path.

The sensor extension pads can also be object detection sensors in their own right, so that an object can be placed directly on the extension pads for identity or on the extended identity pads when an additional piece of the system is present. For example, a playset with interchangeable buildings could allow a toy car to be detected either on the roof of a parking garage add-on building or on the base playset when no building is present.

### Applications

The sensor extension concept can be used in a variety of quite different applications. Several examples are given below.

### Objects with Built-in Sensors

Sensor extensions allow systems that work with objects such as trading cards and figures to include sensors within the objects. In such a system, the base unit includes sensor extension pads that line up with pads in the objects. The pads in the objects are then connected to sensor pads. All sensors and extension pads are fully insulated from the user, and the objects do not require any electronics.

When an object is placed on or in the base, the object's sensors become active and can be used by the base. The sensor extensions in the object are low-cost allowing the objects to each have a unique sensor configuration.

One application of the sensor extension system 100 is an interactive trading card game. FIG. 2 shows a first embodiment interactive trading card game 130. This first embodiment interactive trading card game 130 shows the basic concept of the game system, but does not use sensor extensions. The interactive trading card game 130 includes an electronic card holder 132 that accepts a card 134 and holds it in a card holder frame 136. The card 134 is one of many interchangeable cards that can be used with the electronic card holder 132. The cards 134 and electronic card holder 132 are configured so that the electronic card holder 132 can uniquely identifying the card 134. In addition, the card holder 132 includes a capacitive sensing system that allows players to interact with the game.

There are several options for implementing the capacitive sensing system. The easiest to implement would be a set of buttons 138 around the periphery of the electronic card holder 132, outside of the card holder frame 136. Each card would include labels 140 for the buttons 138. The buttons 138 may be capacitive touch sensors or they may be mechanical switch buttons. Such a solution would work well, but it would increase the size of the holder and limit the design options for the cards.

FIG. 3 shows a second embodiment interactive trading card game 150. This embodiment has an array of touch sensor 158 inside of a card holder frame 156 on an electronic card holder 152. When a card 154 is placed in the card holder frame 156, the array of touch sensor 158 is under the card 154 and is configured to sense touches through the card 154. This would also work, and it could be a better solution than a set of buttons 138 around the periphery of the electronic card holder 132 in the first embodiment of FIG. 2. The drawbacks of this second embodiment interactive trading card game 150 are that it either requires a complex system that allows detection of touch at an x-y location, or it limits touch locations to a set of fixed spots.

What is needed is a simple, low-cost system that allows customized touch locations on each card. It is possible to build the touch sensors into the cards. Using low-cost conductive carbon ink or hot-stamped foil, the touch locations and their connecting traces can be embedded into the cards. Unfortunately, the cards and the holder would ordinarily need to include exposed contacts to make the connection between the sensors in the card and the holder's electronics, as illustrated in FIG. 4. FIG. 4 shows a third embodiment interactive trading card game 170. This embodiment has one or more capacitive touch sensors 178 embedded in a card 174. When the card 174 is placed inside of a card holder frame 176 on an electronic card holder 172, card electrical contacts 180 on the back of the card 174 make direct physical and electrical contact with card holder electrical contacts 182 in a matching location on the electronic card holder 172.

Replacing the electrical contacts 180, 182 with sensor extensions allows the card 174 and electronic card holder 172 to be connected capacitively instead, as illustrated in FIG. 5. FIG. 5 shows a fourth embodiment interactive trading card game 190. This embodiment has one or more capacitive touch sensors 198 embedded in a card 194. The capacitive touch sensors 198 are electrically connected to one or more card extension pads 200. The electronic card holder 192 has one or more card holder extension pads 202 in locations that underlie the card extension pads 200 when the card 194 is placed in a card holder frame 196 on the electronic card holder 192. By including card holder extension pad 202 in the electronic card holder 192 that align with card extension pads 200 in the card 194, such a system can be implemented using capacitive coupling instead of conductive contacts. The electronics in the electronic card holder 192 and the capacitive touch sensors 198 in the card 194 are isolated. This makes the system simpler and more durable. There is no wear on electrical contacts, and no chance for the system to be damaged by static electricity.

### Multi-Layer Sensors

The sensor extension concept can be used to build multi-layer sensor assemblies that don't require conductive connections between the layers. This allows, for example, large touch areas to be placed on a separate layer from that used for routing and capacitively coupled to extension pads on the routing layer. The touch areas may be constructed on the opposite side of the substrate that includes the routing layer, or the touch areas may be on a separate assembly, such as incorporated into a printed label on top of the sensor assembly.

This technique can make routing easier by reducing the size of sensor pads that signals must be routed around. Sensor extension coupling is dependent on area, so if narrow connecting traces are used, it is possible to route the connecting traces for other sensors under a sensor's extended touch area. FIGS. 7A-7C shows this type of application. In the example of FIGS. 7A-7C, many connecting traces must be routed in a narrow area. A second layer with large touch areas is placed above the routing layer. FIG. 7A shows a lower layer 220 with several lower layer primary extension pads 224 on a lower layer substrate 222. Several lower layer traces 226 are routed on the lower layer substrate 222, some of which are routed to the lower layer primary extension pads 224 and some of which are traces to other sensors 228. FIG. 7B shows a top layer 230 with several top layer secondary extension pads 234 on a top layer substrate 232. The top layer secondary extension pads 234 can fill the entire width of the top layer substrate 232 since room does not have to be reserved for the running of traces. FIG. 7C shows a combined assembly 240 comprising of the top layer 230 overlaid on the lower layer 220 with the lower layer trace 226 routed under the top layer secondary extension pads 234.

In FIGS. 7A-7C, the top layer 230 has top layer secondary extension pads 234 that function as sensor pads as well. In other embodiments, the top layer 230 has separate sensor pads conductively connected with the top layer secondary extension pads 234 via traces.

In the embodiment of FIGS. 7A-7C, the top layer 230 is place on the top layer substrate 232 and the lower layer 220 is placed on the lower layer substrate 222. In other embodiments, the top layer 230 and lower layer 220 are place on opposite sides of the same substrate, which also serves as an insulating layer.

### Sensor Matrix

Another application is a sensor matrix. A sensor matrix has row touch sensors and column touch sensors arranged in a grid. A user triggers one or more row sensors and one or more column sensors when touching the matrix, allowing the x-y touch position to be determined. A sensor matrix can be constructed with multiple layers because the row and column sensors cross. Sensor extensions allow this routing to be accomplished with no conductive connections between the layers.

FIGS. 8A-8C show the various components of a sensor matrix 270. FIG. 8A shows a row sensor layer 250 with a plurality of row sensor pads 252. The row sensor pads 252 are arranged in rows and electrically connected by row sensor traces 254. Each row of row sensor pads 252 is electrically connected to one of a plurality of secondary extension pads 256 via a row sensor trace 254. FIG. 8B shows a column sensor layer 260 with a plurality of column sensor pads 262. The column sensor pads 262 are arranged in columns and electrically connected by column sensor traces 264. Each column of column sensor traces 264 is electrically connected to one of a plurality of primary traces 268. Some others of the plurality of primary traces 268 are each electrically connected to one of a plurality of primary extension pads 266. FIG. 8C shows the row sensor layer 250 of FIG. 8A overlaid with the column sensor layer 260 of FIG. 8B to make the sensor matrix 270. The two layers can be constructed as separate assemblies and then joined, or fabricated on opposite sides of a single substrate. In either case, the substrate should be thin in order to maximize capacitance between the extension pads and to equalize the sensitivity of the top and bottom layers to touch.

### Extension Pads on Pcbs

Sensor extension pads can be placed directly on a PCB. This allows the capacitive sensing electronics to be connected to a sensor assembly using low-cost methods such as pressure-sensitive adhesive. This can save space, especially height, in space-sensitive applications. FIG. 9 shows this application. A sensor assembly 280 has one or more sensor pads 282, each electrically connected to a secondary extension pad 284. A printed circuit board 286 has one or more primary extension pads 288, each electrically connected to the circuitry 290 of the printed circuit board 286. The sensor assembly 280 is coupled to the printed circuit board 286 with adhesive 292.

### Sensor Extensions in Packaging

Sensor extensions that couple to sensors in a product can be incorporated into the product's packaging. This enables in-store try-me and other features without requiring either additional electronics in the packaging or elaborate packaging that allows access to the product. FIG. 10 shows an example of this application. A product 302 is enclosed in a package 300. The package 300 has a window 310 to allow a prospective buyer to see the product 302 or a portion thereof. The package 300 has a sensor extension unit 304 attached to the inside front of the package 300. The sensor extension unit 304 has one or more touch sensor pads 306, each electrically connected to a secondary extension pad 308. The secondary extension pads 308 are positioned on the package 300 so that they align with primary extension pads on the product 302. The sensor pads 306 are aligned with graphics on the exterior of the package 300 to indicate to a prospective buyer where to touch to activate features of the product 302.

### Product Displays Using the Product as a Sensor Extension

Sensor extensions can be used to produce an in-store product display that uses the product itself as a sensor extension. For example, a display could include an array of sensor extension pads designed for plastic bottles of cleaning product to sit on. The plastic bottle acts as the insulating layer. The conductive cleaner itself forms the extension pad and touch pad and is covered by the plastic bottle.

The display would include electronics that react when a shopper touches one of the bottles. This could include flashing lights, playing sounds, or dispensing a coupon, among other actions. In effect, the entire portion of the container that is in contact with the product becomes a touch sensor. FIGS. 11A and 11B show an example of a product display 320 using sensor extensions. The product display 320 has a display platform 322 and an electronics module 324. The display platform 322 has one or more primary extension pads 326 that are electrically connected to the electronics module 324. One or more conductive products 328 are placed on the primary extension pads 326. When a potential buyer touches one of the conductive products 328, the electronics module 324 detects the change in capacitance and performs actions as described above.

What is claimed is:

1. A sensor extension system, comprising:
a primary sensor comprising a primary extension pad of conductive material and comprising a primary conductive trace;
a measurement electronics module conductively connected to the primary extension pad via the primary conductive trace, the measurement electronics module configured for measuring a capacitance between the primary conductive trace and a system ground;
a sensor extension with a secondary extension pad comprising conductive material, the sensor extension configured for physically coupling with the primary sensor such that the primary extension pad is adjacent to the secondary extension pad; and
an insulating layer between the primary sensor and the sensor extension.

2. The sensor extension system of claim 1, further comprising:
a sensor pad comprising conductive material, the sensor pad conductively connected to the secondary extension pad via a secondary conductive trace.

3. The sensor extension system of claim 1, wherein:
the primary extension pad and the secondary extension pad are at least partially overlapping.

4. The sensor extension system of claim 1, wherein:
the primary extension pad and the secondary extension pad are co-planar.

5. A card reading system comprising:
an electronic card holder comprising an electronics module and one or more primary extension pads, the extension pads of a conductive material and conductively connected to the electronics module;
a plurality of electronic cards, each of the electronic cards with one or more secondary extension pads of conductive material;
wherein each of the electronic cards is configured for detachably coupling to the electronic card holder in a specific alignment; and
wherein each of the electronic cards has at least one of the secondary extension pads aligned with at least one of the primary extension pads when the electronic card is detachably coupled to the electronic card holder in the specific alignment.

6. The card reading system of claim 5, wherein:
each of the electronic cards has one or more sensor pads of conductive material, each of the sensor pads conductively connected to one of the secondary extension pads.

7. The card reading system of claim 6, wherein:
at least one of the electronic cards has at least one of the sensor pads on that card in a different location than the sensor pads on another of the electronic cards.

8. The card reading system of claim 5, further comprising:
an insulating layer on the electronic card holder covering the primary extension pads.

9. The card reading system of claim 5, further comprising:
an insulating layer on each of the electronic cards covering the secondary extension pads.

10. A product packaging system comprising:
a package configured for holding an electronic device in a specific alignment relative to the package; and
a sensor extension unit coupled to the package.

11. The product packaging system of claim 10 wherein:
the sensor extension unit has one or more sensor pads;
the sensor extension unit has one or more secondary extension pads each conductively connected to one of the sensor pads; and
the sensor extension unit is positioned on the package such that when the electronic device is in the specific alignment relative to the package, at least one of the secondary extension pads aligns with a primary extension pad on the electronic device.

12. A multi-layered sensor comprising:
a lower layer comprising one or more lower layer primary extension pads, and one or more primary conductive traces, wherein each of the primary extension pads is conductively connected to one of the primary conductive traces;
a top layer comprising one or more secondary extension pads;
an insulating layer between at least a portion of the lower layer and at least a portion of the top layer;
wherein the top layer overlays the lower layer such that at least one of the secondary extension pads overlays one of the primary extension pads; and
wherein at least one of the primary conductive traces is routed underneath at least one of the secondary extension pads.

13. A multi-layered sensor comprising:
a lower layer comprising, one or more lower layer primary extension pads, and one or more primary conductive traces, wherein each of the primary extension pads is conductively connected to one of the primary conductive traces;
a top layer comprising one or more sensor pads, one or more secondary conductive traces and one or more secondary extension pads, wherein each of the sensor pads is conductively connected to one of the secondary extension pads with one of the secondary conductive traces;
an insulating layer between at least a portion of the lower layer and at least a portion of the top layer;
wherein the top layer is overlays the lower layer such that at least one of the secondary extension pads overlays one of the primary extension pads; and
wherein at least one of the primary conductive traces is routed underneath at least one of a group of: one of the secondary conductive traces, one of the sensor pads, and one of the secondary extension pads.

14. A sensor matrix comprising:
a row sensor layer with a plurality of sensor rows, each sensor row with a secondary extension pad and a plurality of row sensor pads, the secondary extension pad and row sensor pads conductively connected by row sensor traces;
a column sensor layer with a plurality of primary traces, a plurality of primary extension pads and a plurality of sensor columns, each sensor column with a plurality of column sensor pads conductively connected by row sensors, wherein each of the primary extension pads is conductively connected with one of the primary traces; wherein each of the sensor columns is conductively connected with one of the primary traces;
an insulating layer between the row sensor layer and the column sensor layer; and
wherein the column sensor layer overlays the row sensor layer and aligned such that at least one of the primary extension pads overlays one of the secondary extension pads.

15. The sensor matrix of claim 14 wherein:
wherein the column sensor layer has a plurality of column sensor gaps between the column sensor pads;
wherein the column sensor gaps overlay the row sensor pads;
wherein the row sensor layer has a plurality of row sensor gaps between the row sensor pads; and
wherein the column sensor pads overlay the row sensor gaps.

16. A product display system comprising:
a display platform with one or more sensor pads; and
an electronics module conductively connected to each of the sensor pads, wherein the electronics module is configured for measuring a capacitance of each of the sensor pads, wherein the electronics module is configured for triggering an action if the capacitance of one of the sensor pads changes by more than a threshold amount.

17. The product display system of claim 16 further comprising:
one or more products comprising conductive material, each product placed on one of the sensor pads.

18. The product display system of claim 17 further comprising:
an insulating layer overlaying the sensor pads.
